(19) United States
(12) Patent Application Publication
(10) Pub. No.: US 2011/0253614 A1
(43) Pub. Date: Oct. 20, 2011

(54) VERSATILE UNFOLDING SOLAR DEPLOYMENT SYSTEM

(75) Inventors: Seamus Curran, Houston, TX (US); Nathaniel Morgan, Houston, TX (US); Nigel Alley, Houston, TX (US)

(73) Assignee: University of Houston, Houston, TX (US)

(21) Appl. No.: 13/010,406

(22) Filed: Jan. 20, 2011

Related U.S. Application Data
(60) Provisional application No. 61/296,524, filed on Jan. 20, 2010.

(51) Int. Cl. B01D 36/00; C02F 1/00; H01L 31/045

(52) U.S. Cl. 210/239; 136/245; 210/251

(57) ABSTRACT

A versatile solar deployment system may provide one or more scalable solar deployment units. A solar deployment unit may include a chassis, a panel support provided by the chassis, and one or more solar panels coupled to the panel support, wherein the solar panels are folded together in an undeployed position, and the solar panels are unfolded in a deployed position. Alternatively, a solar deployment unit may include a rolling mechanism providing a rotating shaft and a flexible panel. One end of the flexible panel is secured to the rotating shaft, the flexible panel is rolled around the rotating shaft to retract the flexible panel into an undeployed position, and the flexible panel is unrolled to deploy the flexible panel into a deployed position.

### RELATED APPLICATIONS

This application claims the benefit of U.S. Provision Patent Application No. 61/296,524 to Curran et al., filed on Jan. 20, 2010, which is incorporated herein by reference.

### STATEMENT REGARDING FEDERALLY SPONSORED RESEARCH

The present invention was made in part with government support under Grant No. DE-FG36-08G088008 awarded by the Department of Energy. The government may have certain rights in this invention.

### FIELD OF THE INVENTION

This invention relates to portable solar energy units and those that may be easily installed to a fixed location on a larger scale. More particularly, systems and methods discussed herein are related to deploying solar energy panels.

### BACKGROUND

Permanent installation of solar energy generation units involves considerably high labor costs due to their inherent, inefficient design from an installation perspective. For instance, a support assembly, such as a rack, may be installed to a desired location and the individual solar panels may be secured to the support assembly one by one. Installation of the support assembly and panels is extremely time consuming, and may require more than one person to install the panels. This issue is addressed herein with the versatile unfolding solar deployment system.

The following description relates to the design, architecture, and fabrication of a series of portable solar energy generation units which utilize new methods of panel deployment that can be configured for permanent installation or temporary applications. More specifically, these units are built from a common base system which then has application related parameters and design elements added to construct the required system specifications. The present invention enables a quicker, safer, and cheaper installation and operation cost of solar units relative to permanent units designed for roofs.

The units may be preassembled and may require little time or skill for permanent and/or temporary installation to either a standing structure or an appropriate ground foundation, which may include, but is not limited to, roofs, walls, awnings, sky-tunnels, signs, billboards, fences, outcrops, rock faces, and the like. Further, the units may be modular to satisfy various power generation and dimensional requirements.

The portable units are advantageous because of their simple and quick deployment and retraction and their ease of use. The units can be used for human portable needs, such as small scale power generation, and large needs, such as trailer based portable devices or generators capable of operating on a moving/stationary vehicle for civil, humanitarian, or military applications. The design described herein enables a larger power generating capacity for the size of the retracted device by allowing a larger number of panels to be deployed and retracted. Costs and system quality are critical factors for solar energy generating systems. The design described herein is based upon an innovative unfolding deployment concept which enables higher power outputs compared to similar sized devices currently available.

### SUMMARY

In one implementation, a solar deployment unit may include a chassis, a panel support provided by the chassis, and one or more solar panels coupled to the panel support, wherein the solar panels are folded together in a undeployed position, and the solar panels are unfolded in a deployed position.

In another implementation, a solar deployment system may include one or more solar units. Each solar unit may include a chassis and one or more solar panels. The solar panels are retained within the chassis in an undeployed position, and the solar panels extend from the chassis in a deployed position. Each solar unit may also include an electronic control unit provided within the chassis, wherein the electronic control unit manages the power generated by the solar panels.

In yet another implementation, a solar deployment unit may include a rolling mechanism providing a rotating shaft and a flexible panel. One end of the flexible panel is secured to the rotating shaft, the flexible panel is rolled around the rotating shaft to retract the flexible panel into an undeployed position, and the flexible panel is unrolled to deploy the flexible panel into a deployed position.

The foregoing has outlined rather broadly various features of the present disclosure in order that the detailed description that follows may be better understood. Additional features and advantages of the disclosure will be described hereinafter, which form the subject of the claims.

### BRIEF DESCRIPTION OF THE DRAWINGS

For a more complete understanding of the present disclosure, and the advantages thereof, reference is now made to the following descriptions to be taken in conjunction with the accompanying drawings describing specific embodiments of the disclosure, wherein:

FIG. 1 is an illustrative implementation of a side view of a portable solar deployment unit;

FIG. 2 is an illustrative implementation of a portable solar deployment unit with panels vertically deployed;

FIG. 3 is a illustrative implementation of a portable solar deployment unit with panels horizontally deployed;

FIGS. 4a and 4b are illustrative implementations of a solar deployment unit in a retracted position;

FIG. 5 is an illustrative implementation of a structural support for a solar deployment unit;

FIGS. 6a-6e are illustrative implementations of top, side, and front views of a solar deployment unit with and without a cover;

FIG. 7 is an illustrative implementation of a solar deployment unit partially deployed on structural supports;

FIGS. 8a-8c are illustrative implementations of top, side, and front views of a solar deployment unit partially deployed on structural supports;

FIG. 9 is an illustrative implementation of a solar deployment unit fully deployed on structural supports;

FIGS. 10a-10c are illustrative implementations of top, side, and front views of a solar deployment unit fully deployed on structural supports;

FIG. 11 is an illustrative implementation of a mobile solar deployment unit;

FIG. 12 is an illustrative implementation of a mobile solar deployment unit in a deployed position;

FIG. 13 is an illustrative implementation of a personal mobile solar deployment unit in an undeployed position;

FIGS. 14a-14c are illustrative implementations of front, side, and back views a personal mobile solar deployment unit in an undeployed position;

FIG. 15 is an illustrative implementation of a personal mobile solar deployment unit in an deployed position;

FIGS. 16a-16c are illustrative implementations of front, side, and top views a personal mobile solar deployment unit in an deployed position;

FIG. 17 is an illustrative implementation of a trailer solar deployment unit in a deployed position;

FIG. 18 is an illustrative implementation of a flexible solar panel unit;

FIGS. 19a-19c are illustrative implementations of plan, elevation, and end view of a flexible solar panel unit;

FIG. 20 is an illustrative implementation of a first view of a flexible solar panel unit installed on a roof;

FIG. 21 is an illustrative implementation of a second view of a flexible solar panel unit installed on a roof;

FIG. 22 is an illustrative implementation of a flexible solar panel unit utilizing structural supports;

FIG. 23 is an illustrative implementation of unfolding solar deployment units installed on a roof;

FIG. 24 is an illustrative implementation of a portable water purification system;

FIG. 25 is an illustrative implementation of the components of a water purification system;

FIGS. 26a-26c are illustrative implementations of a plan, elevation, and end view of the components of a water purification system;

FIG. 27 is an illustrative implementation of a filter;

FIG. 28 is an illustrative implementation of a cross-section of a filter; and

FIGS. 29a-29c are illustrative implementations of a plan, elevation, and end view of a filter.

### DETAILED DESCRIPTION

In the following description, certain details are set forth such as specific quantities, concentrations, sizes, etc. so as to provide a thorough understanding of the various embodiments disclosed herein. However, it will be apparent to those of ordinary skill in the art that the present disclosure may be practiced without such specific details. In many cases, details concerning such considerations and the like have been omitted inasmuch as such details are not necessary to obtain a complete understanding of the present disclosure and are within the skills of persons of ordinary skill in the relevant art.

Referring to the drawings in general, it will be understood that the illustrations are for the purpose of describing particular embodiments of the disclosure and are not intended to be limiting thereto. While most of the terms used herein will be recognizable to those of ordinary skill in the art, it should be understood that when not explicitly defined, terms should be interpreted as adopting a meaning presently accepted by those of ordinary skill in the art.

The following discussion provides a description of versatile unfolding solar deployment systems and methods. Versatile unfolding solar deployment systems may include one or more modular portable solar deployment units, which allow the systems to be scaled to meet desired needs. Portable solar deployment units providing improved panel deployment may be configured for permanent installation or temporary applications. These units utilize a common base system, which has application related parameters and design elements that may be added to meet the particular requirements and specifications for a desired system. The units enable a quicker, safer, and cheaper installation and lower operation cost for the solar units.

Preassembled units may be integrated with a number of ‘modules’ with varying functionality and complexity as per the power generation and dimensional requirements of the application. For example, permanent install designs may be expandable to allow the user to easily install additional arrays as required in a ‘plug and play’ fashion. These units provide fully customizable panel arrays, and the dimensions of the units customizable depending upon the restrictions of the application. Each individual array may contain 2 to 1,000 panels. However, as solar panel development progresses and more efficient organic or thin film photovoltaics become available, this number may increase accordingly. The power generation capacity for a versatile unfolding solar deployment system may scale in a range from 50 W to 100 MW. A versatile unfolding solar deployment system may have many uses including, but not limited to, portable, residential, small commercial, military, charity, non-government organizations (NGOs), large commercial to industrial power generation applications (such as solar farms), and many other applications.

The advantage of these portable units is their ease of use and speed of deployment and retraction. They can be used for individual portable needs, such as small scale power generation, to large scale needs, such as trailer based portable devices or as a generator capable of operating on a moving/stationary vehicle for civil, humanitarian, or military applications. While the retracted size of the device is relatively small, the versatile unfolding solar deployment system enables a larger power generating capacity. Costs and system quality are critical factors for solar energy generating systems. The versatile unfolding solar deployment systems and methods described herein are based upon an innovative unfolding deployment concept which enables higher power outputs when compared to similarly sized devices.

This can add to the development of an electrical supply to regional areas without the necessity to build a major grid infrastructure. By using the generation and storage components of the portable units, this can enable the implementation of a DC supply where necessary or by including a DC to AC converter, supply AC power required by many electrical components. This can be done by direct connection to the portable unit, or providing leads from the unit to home/work places.

Base Unit

The base unit design is the fundamental foundation upon which all structural permutations and possible conceivable applications for this invention are realized. The base unit provides a modular design that allows additional components to be added to provide additional functionality. Further, the base unit design provides a scalable versatile unfolding solar deployment system that can be expanded and/or upgraded to meet desired needs.

The solar panels in a versatile unfolding solar deployment system can be deployed in a number of ways. For example, the panels may unfold from a base unit into a vertical position. The panels may also be adjusted by pivoting, swinging, or rotating the panels into a horizontal orientation using a winch, crank, gear, pulley, or related mechanical apparatus. In other implementations, the panels may unfold from packed configuration into a standard horizontal orientation that is adjustable to a vertical position using a winch, crank, gear, pulley, or related mechanical apparatus. Base unit deployment can be achieved either manually (human powered) or can be automated using a motor or other appropriate actuation device (such as crank, winch, pulley, geared motor, hydraulic/pneumatic actuator, a combination thereof, and the like). The panels may be deployed in the horizontal configuration by use of hinges, slide arms, joints, rails, or interlocking connections.

In some implementations, flexible panels or smaller interconnected rigid panels (with small radius of curvature=>1 mm) may be stored in a roll. These panels can be rolled out and deployed along an appropriate structural support. In yet another implementation, panels may be deployed in a similar manner as an umbrella. These deployment processes may be assisted by employing a friction reducing mechanism(s) (e.g. guides, wheels, bearings or the like) to aid ease of deployment—in particular for larger sized systems.

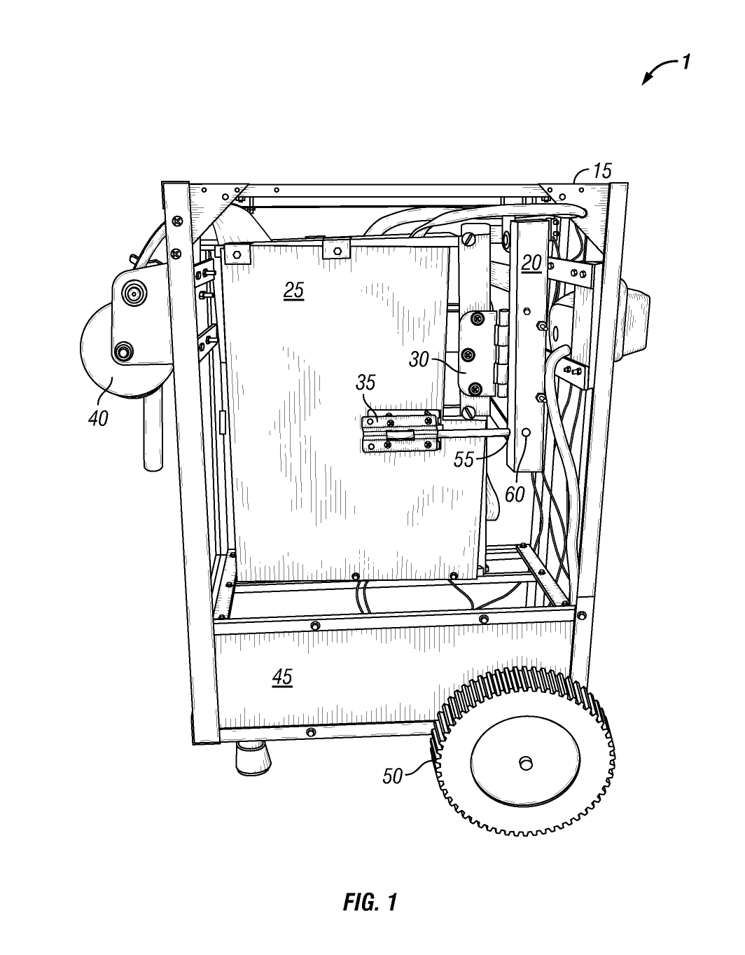

FIG. 1 is an illustrative implementation of a side view of a portable solar deployment unit 1. Portable solar deployment unit 1 may provide chassis 15, panel support 20, solar panels 25, hinges 30 and 32, locking mechanisms 35, winch 40, electronics housing 45, and wheels 50. Chassis 15 provides the supporting structure for portable solar deployment unit 1. Panel support 20 is integrated with chassis 15 or may be secured to chassis 15 and supports the weight of panels 25. Panel support 20 may adjustable to allow panels 25 to be adjusted into a vertical position, horizontal position, or angled position. The size, weight, dimensions, and the like of portable solar deployment unit 1 may be minimized to allow for easy transport, handling, and deployment of the unit. Hinges 30 attach panels 25 to panel support 20 and allow panels 25 to be deployed from portable solar deployment unit 1. Additionally, each panel 25 may be hinged to another panel by hinges 32 (FIG. 3). In other implementations, rather than placing hinges 32 between the panels 25, the hinges may be placed at the edges of panels 25. Panels 25 may be any suitable type of solar panel, including, but not limited to, thin film solar cells, flexible cells, rigid cells, and the like.

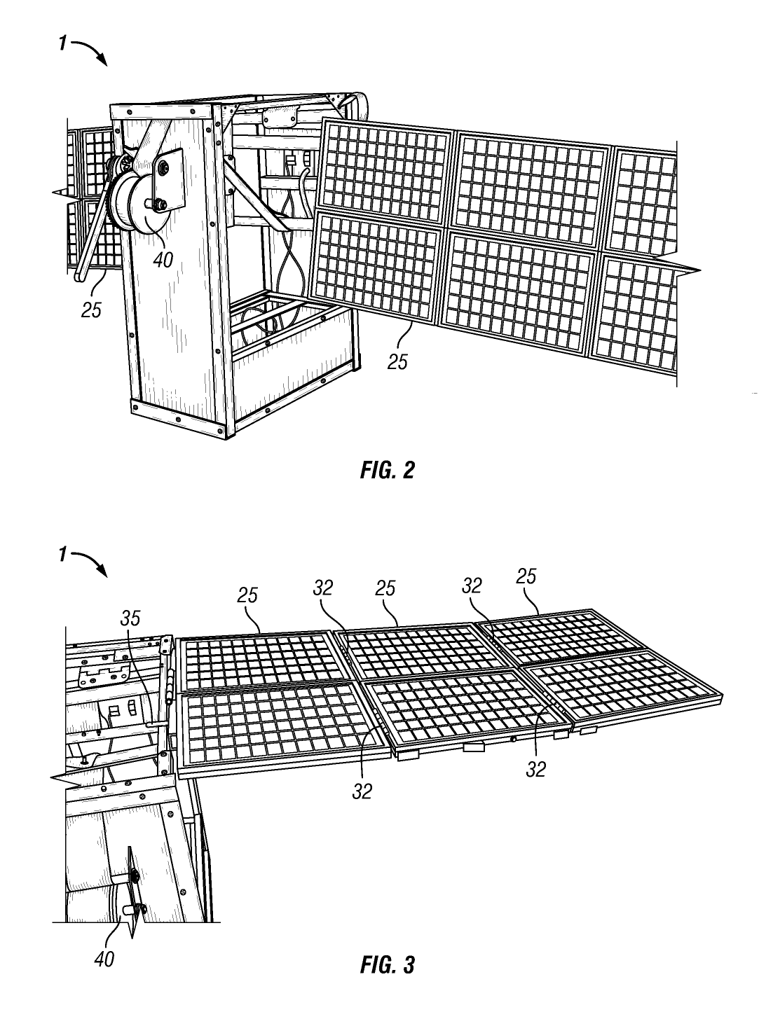

Locking mechanisms 35 attached to panels 25 secures to first opening 55 in panel support 20 to lock the panels in a retracted position as shown, thereby preventing accidental deployment and/or damage to the panels. Locking mechanism 35 may be disengaged to allow panels 25 to be unfolded from chassis 15 for deployment of the panels. Locking mechanism 35 may be secured to a second opening 60 in panel support 20 when panels 25 are deployed to secure the panels in a deployed position (FIG. 2). While locking mechanisms 35 is shown engaging panel support 20, in other implementations, the locking mechanism may be arranged in any suitable manner, such as engaging chassis 15. Panels 25 may be unfolded and locked into position by a user. However, in other implementations, a deployment mechanism may be utilized to deploy and retract panels 25. Any suitable mechanical apparatus may be utilized to deploy and retract panels 25, such as a crank, gear, pulley, motor, hydraulic or pneumatic actuator, or a combination thereof. For example, the panel 25 that is connected to panel support 20 by hinge 20 may provide a gear assembly that is coupled to a motor. When the motor is operated, the gears cause panels 25 to turn out from chassis 15 for deployment. The motor may be operate in the opposite direction to retract panels 25 back into chassis 15. A adjustment mechanism, such as winch 40, coupled to panel support 20 allows the panels 25 to be adjusted between vertical and horizontal positions. Winch 40 may be actuated to adjust panels 25 to a desired position, including a horizontal position, vertical position, or an angled position. As with the deployment mechanism, any suitable mechanical apparatus may be utilized to adjust the position of panels 25. Electronics housing 45 may house electronics utilized by the system, such as an electronic control unit, batteries, power converters, motors, air compressors, controllers, and the like. An electronic control unit may provide a CPU, processor, microprocessor, controller, or the like and circuitry utilized to manage and control power generated by panels 25 and may also control various electronic features provided by the unit. For example, rechargeable batteries may be provided in electronics housing 45 to store the power generated by panels 25. Electronics housing 45 may house charging circuitry utilized to recharge the batteries. Each panel 25 may include imbedded electronics, including, but not limited to, a microinverter, power optimizer, and the like. In some implementations, chassis 15 may provide a power converter to convert the power from DC to AC power, from AC to DC power, and/or from DC to DC power at a desired voltage level. Motors or air compressors utilized for deployment and/or position adjustment of panels 25 may also be provided in electronics housing 45 or in chassis 15. Various controllers, such as controllers utilized to manage the power generated by panels 25, recharging controllers, deployment controllers, position adjustment controllers and the like, may be provided in electronics housing 45. Electronics housing 45 may include a cover (not shown) to protect the electronic components from severe weather. The cover may also provide a gasket or the like to provide a substantially water proof seal when secured to electronics housing 45, thereby preventing potential damage to the electronics from water, rain, and the like. In some implementations, wheels 50 are attached to chassis 15 allow portable solar deployment unit 1 to be easily moved and transported. The optional wheels 50 may be easily attached or detached from chassis 15 as desired.

FIG. 2 is an illustrative implementation of portable solar deployment unit 1 with panels 25 vertically deployed. FIG. 3 is a illustrative implementation of portable solar deployment unit 1 with panels 25 horizontally deployed. When deployed, panels 25 may be adjusted between horizontal and vertical positions utilizing winch 40. As shown in FIG. 3, locking mechanism 35 may be secured to the second opening in the panel support, thereby securing panels 25 in a deployed position.

FIGS. 4a and 4b are illustrative implementations of solar deployment unit 10 in a retracted position. FIG. 4a illustrates solar deployment unit 10 with cover 65 in place, and FIG. 4b illustrates solar deployment unit 10 with a cover removed. Multiple panels 25 are folded or packed into chassis 15 in the retracted position greatly reducing the dimensions of solar deployment unit 10 in comparison to deployed positions. Note that the size, dimensions, and weight of solar deployment unit 10 may be larger that portable solar deployment unit 1. Solar deployment unit 10 may be particularly suitable for long term deployment. For example, one or more solar deployment unit 10 may be deploy on the roof of a building or house.

Panel Protection/Cleaning—Post Deployment

An integrated semi transparent/transparent shutter mechanism can be incorporated to protect the solar panels. The shutter can either be manually operated by means of a crank, or slide arm or equivalent, or with the aid of a control module connected to a motor or similar driving device. This in turn can become an automated safety feature protecting the modules from storm or severe weather damage. Solar panels may be treated to have a hydrophobic coating which will aid in keeping the panels cleaner for a longer period of use between cleaning cycles—if necessary at all.

Base Unit Modularity and Support

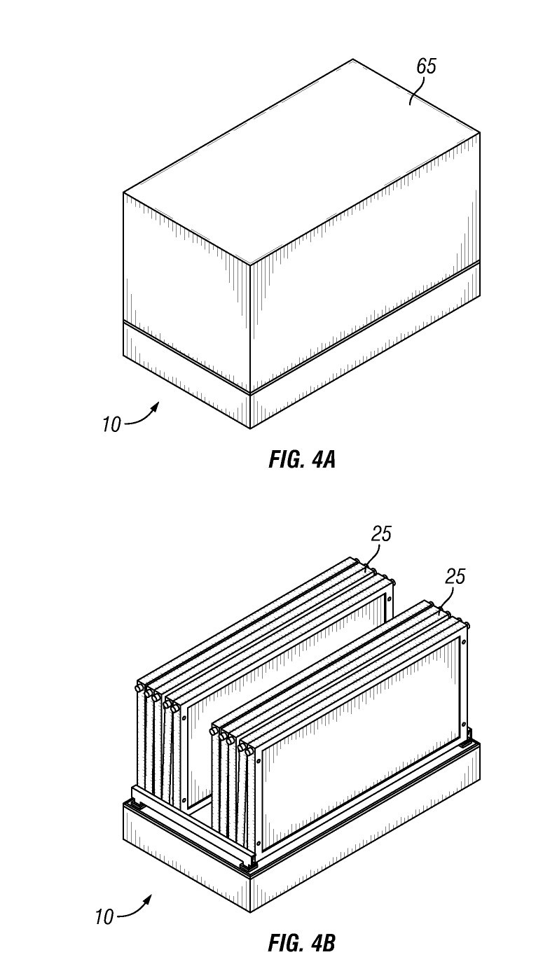

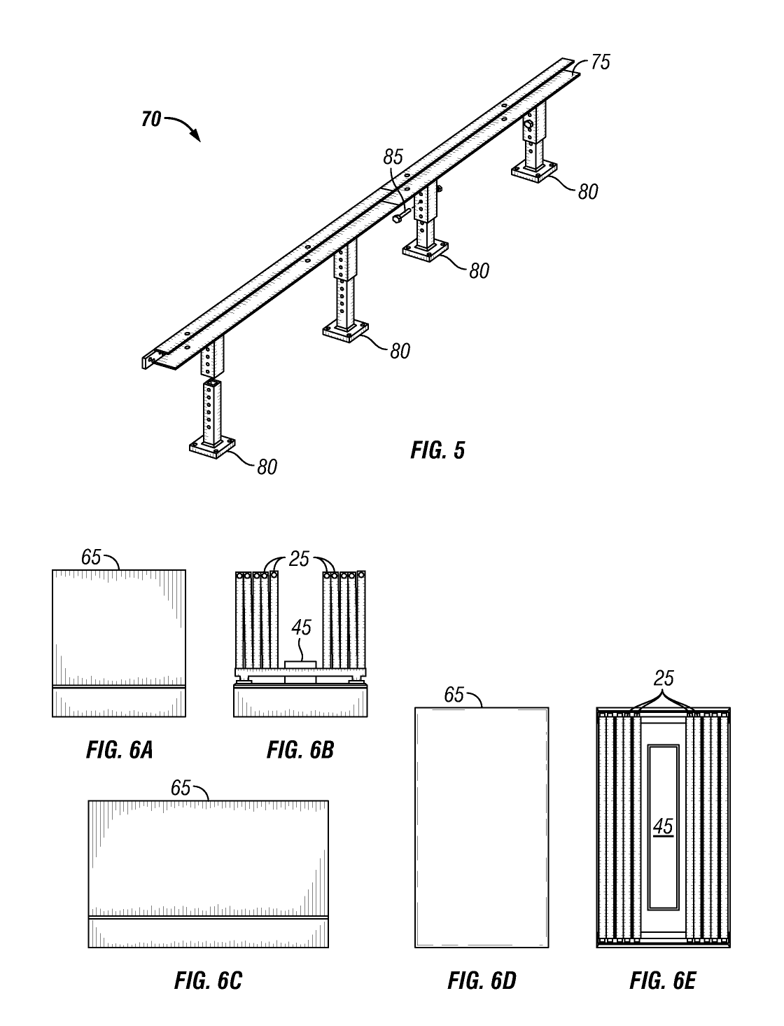

FIG. 5 is an illustrative implementation of a structural support 70 for solar deployment unit 10. Structural support 70 may provide a panel support 75 on which panels 25 are placed. Panel support 75 provides structural support for the deployed panels 25. As shown, panel support 75 is rectangular C-shaped bar providing one open side that is designed to received panels 25 or an extension of the panels. However, in other implementations, any suitably shaped support and/or cross-sectional design may be utilized for panel support 75. In some implementations, pins, wheels, or the like may protrude from the edges of panels 25. The pins, wheels, or the like may fit into the open side of panel support 75, thereby allowing panel supports 75 to act as guide rails during deployment and retraction of the panels. Struts 80 attach to panel support 75 and may bear the weight of structural support 70 and panels 25. Struts 80 may provide telescoping and/or pivotal features that allow the length and angle of the struts to be adjusted for various terrains. In some implementations, the bottom portion of struts 80 may adjustable to modify the angle of the base to accommodate angled terrains or the like. Struts 80 may provide telescoping legs that are secured at a desired length using locking pins 85. The base of strut 80 may be capable of pivoting to a desired angle and being locking in place with a fastener, such as a locking pin. Structural support 70 is scalable and multiple structural supports may be combined and secured together. In the implementation shown, structural supports 70 may be placed at the edges of panels 25. In other implementations, panel support 75 may be flat and wide to allow a single structural support 70 to be utilized near the middle of panels 25.

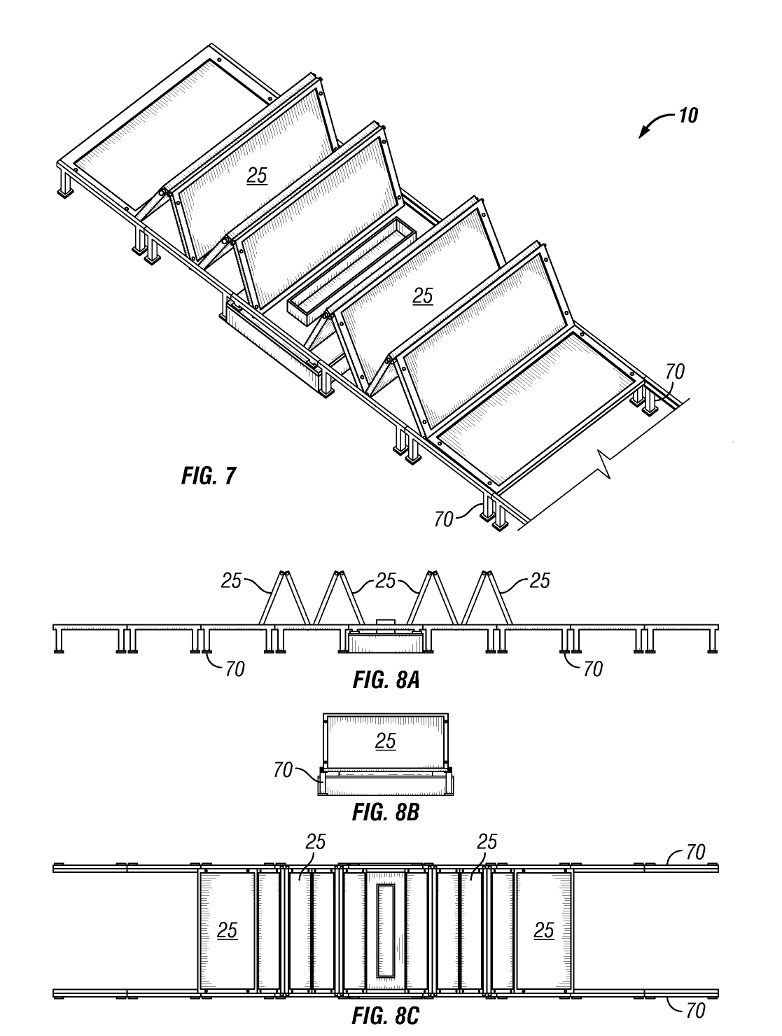

FIGS. 6a-6e are illustrative implementations of top, side, and front views of solar deployment unit 10 with and without a cover 65. Without cover 65, panels 25 of solar deployment unit 10 can be seen in a retracted position. As in the portable unit, electronics housing 45 may provide a variety of electronic components. Electronics housing 45 may also provide connectors, plugs, and the like to allow multiple solar deployment units 10 to be coupled together. The connectors, plugs, and the like may also allow solar deployment units 10 to be coupled to electronic grids, a home or build, batteries, and the like.

FIG. 7 is an illustrative implementation of solar deployment unit 10 partially deployed on structural supports 70. FIGS. 8a-8c are illustrative implementations of top, side, and front views of solar deployment unit 10 partially deployed on structural supports 70. One or more structural support 70 may be utilized with one or more solar deployment units 10. One or more solar deployment units 10 may be connected together by a connector cable or the like to expand the system. The versatile unfolding solar deployment system in its assembled retracted form is fully wired. Panels 25 of solar deployment unit 10 may be easily unfold onto structural supports 70 by a user. The weight of panels 25 is supported by structural supports 70. It should be noted that structural supports 70 are optional and may not be needed in some implementations. Structural supports 70 may be desired when the number of panels 25 increases or when multiple solar units are combined. In some implementations, the thickness of panels 25 may require a certain amount of play or separation of the panels to allow them to easily unfold. Hinges 32 may be slideably coupled to panels 25, such as by a slotted opening in the hinges allowing a fastener to slide while being secured to the hinge. Note that when panels 25 are deployed, slight gaps between panels 25 may be present as a result of the play or separation that allows the panels to be easily deployed. The slotted openings in the hinges may allow the panels to be pushed together to eliminate the gaps and lock the panels together. In some implementations, a rope, cable, or the like may be utilized eliminate the gaps and lock the panels together.

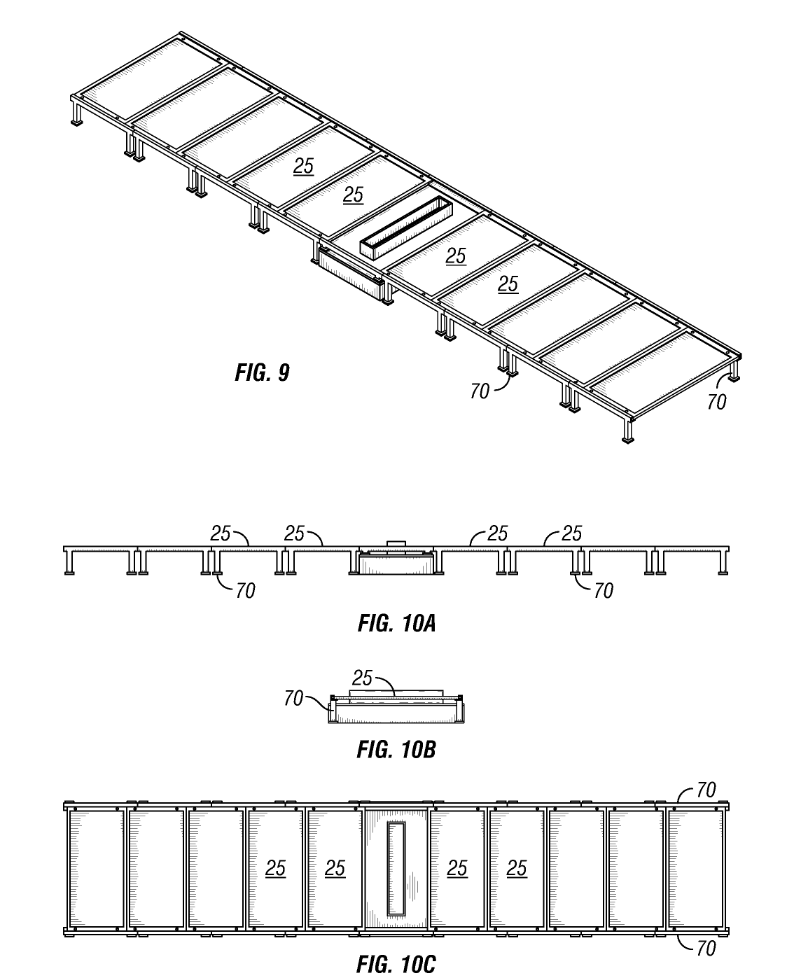

FIG. 9 is an illustrative implementation of solar deployment unit 10 fully deployed on structural supports 70. FIGS. 10a-10c are illustrative implementations of top, side, and front views of solar deployment unit 10 fully deployed on structural supports 70. In the deployed position, panels 25 are unfolded and approximately in the same plane. Structural supports 70 provide support for the weight of panels 25. To aid panel unfolding and overall structural strength and stability of the flat horizontal panel arrays, a support structure is incorporated into the design, such as in FIG. 9. This support structure may be comprised of a metal/plastic section namely a structural shape or similar appropriate material.

Installation/Setup

Once the versatile unfolding solar deployment system is on-site ready to be installed it may simply be positioned to the desired point of deployment and either mechanically attached or locked into position on a preinstalled installation base. For larger solar deployment units, this reduces the amount time a lifting device needs to be on-site thus reducing installation costs further. Portable solar deployment units (e.g. FIGS. 1-3 and 13-16) are lightweight to allow a single person to transport and deploy the system. Solar deployment units (e.g. FIGS. 4 and 6-12) may be larger and designed for long term or permanent deployment. However, some implementations of solar deployment units may also be portable.

Additional Modules Concept

The versatility of the solar deployment units is what makes it such an innovative solar power generation solution. For purposes where there is a requirement to tie the solar power generation system into the electrical grid, a separate module can contain all necessary electrical components/circuitry/connection equipment to enable an electrician to quickly and efficiently carry out the task. For more complex or larger capacity systems, the user may require a greater level of control of the system output and other critical power generation parameters. In order to power sensitive equipment or to accommodate any other specific requirements, additional modules providing the necessary functionality may easily be added.

Expandability

Base units may be connected in series/parallel with more than one unit at a time to expand the power generation capacity. The maximum number of units that may be utilized depends upon space and connection cable power ratings utilized in the system. It is conceivable that the number of arrays x of y panels may range from x=1 to x>1 million as demand for energy grows.

Scalability

The concept of adapting from small to large scale portable or fixed installations is detailed in the various specifications below. Minor modifications to the base unit in terms of materials choice and structural enhancements may be made for more applications and environmental specific requirements as detailed below.

Fixed Installation Specification

For ground installation, the system is installed on either a predefined foundation network on rough terrain. For example, a foundation may provide support for solar deployment unit and the solar panels or one or more supporting structures that are adaptable to different terrains may be utilized. For example, structural supports shown in FIG. 5 provide telescopic supports that may be locked into place at the required length or angle determined by the terrain.

Rooftop/Standing Structure Installation

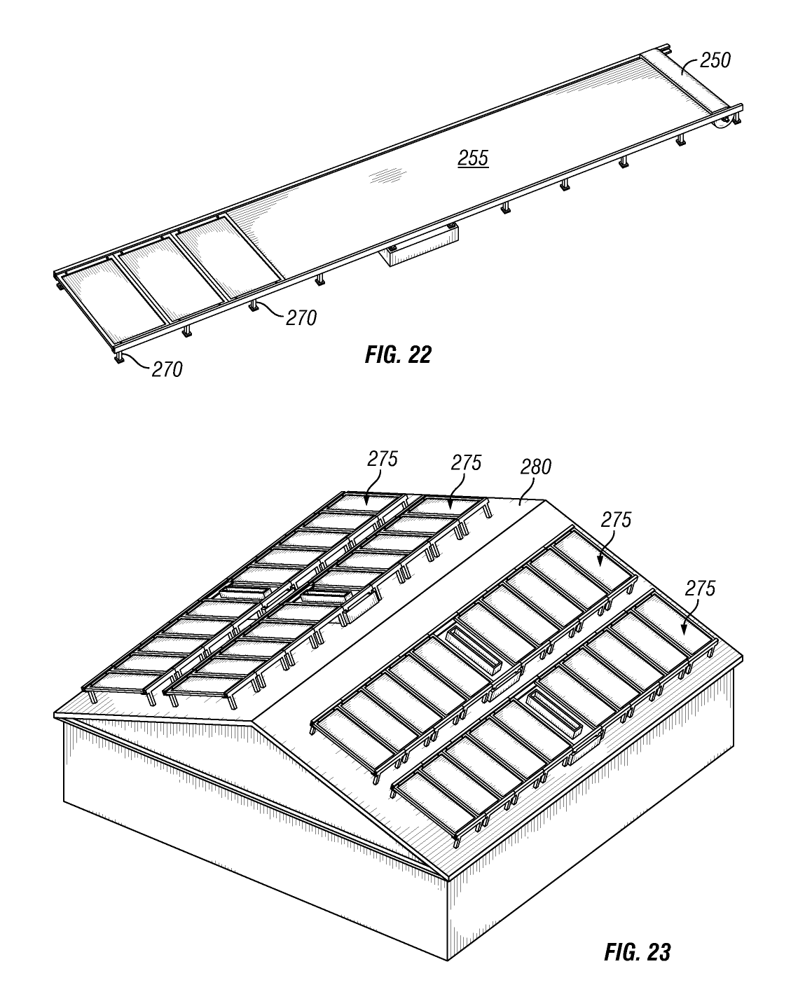

Versatile unfolding solar deployment systems may be installed on a roof with almost any angle/pitch made of any standard material. This can be achieved by means of customizable support legs/struts which are attached/locked into place along the structural shapes (or other shaped cross-sectional support framework) as shown in FIG. 5 and FIG. 22.

Portable Units

Trailer/Vehicle portable systems may provide a systems ranging from 1 array to larger systems based on tractor trailer form factors. These systems can generate power ranging from 1 kW to 100 kW. The portable systems can contain a water treatment facility powered by the solar panels as described in detail below. The purification system is designed to remove filth and dirt particles through a series of filters, but also a desalination system powered by the panels can be attached to the purification system after the water leaves the filters. The housing of a filter system within the chassis of the portable system means that water can be pumped out electronically, filtered, and desalinated (as necessary) as part of the filter network.

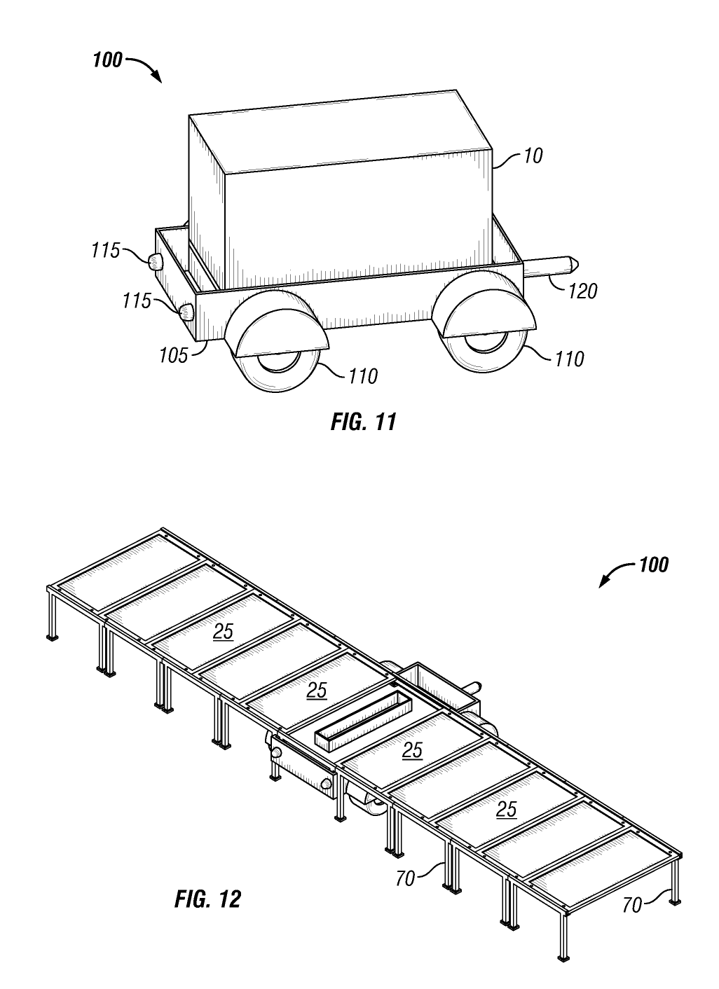

FIG. 11 is an illustrative implementation of a mobile solar deployment unit 100. Mobile solar deployment unit 100 incorporates a mobile attachment 105 with a solar deployment unit 10. Mobile attachment 105 may provide wheels 110, lights/reflectors 115, and a hitch 120. While mobile attachment 105 is shown as a separate component from the chassis, in other implementations, the chassis itself may provide the features of mobile attachment 105. Wheels 110 are not driven. However, in other implementations, it may be desirable to have wheels 110 driven by an electric motor or the like for low speed movement and positioning of mobile solar deployment unit 100. Lights/reflectors 115 are provided for safety purposes when mobile solar deployment unit 100 is towed by a vehicle. Further, hitch 120 allows mobile solar deployment unit 100 to attached to a vehicle for towing.

FIG. 12 is an illustrative implementation of a mobile solar deployment unit 100 in a deployed position. In the deployed position, panels 25 are unfolded and approximately in the same plane. Structural supports 70 provide support for the weight of panels 25.

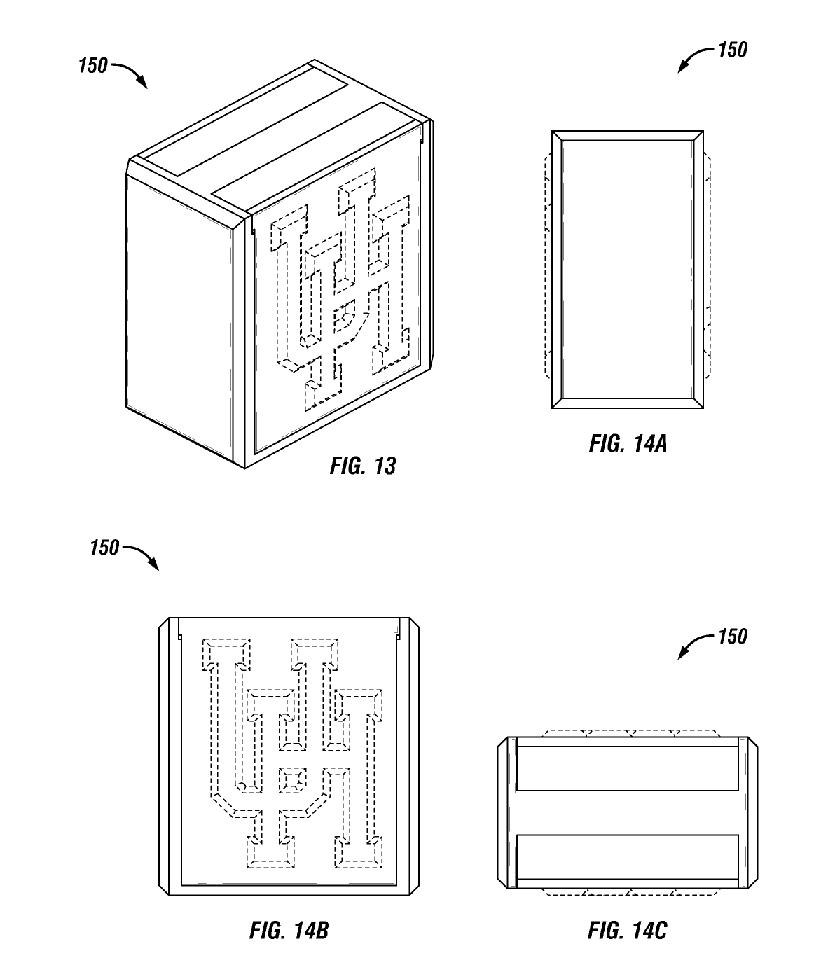

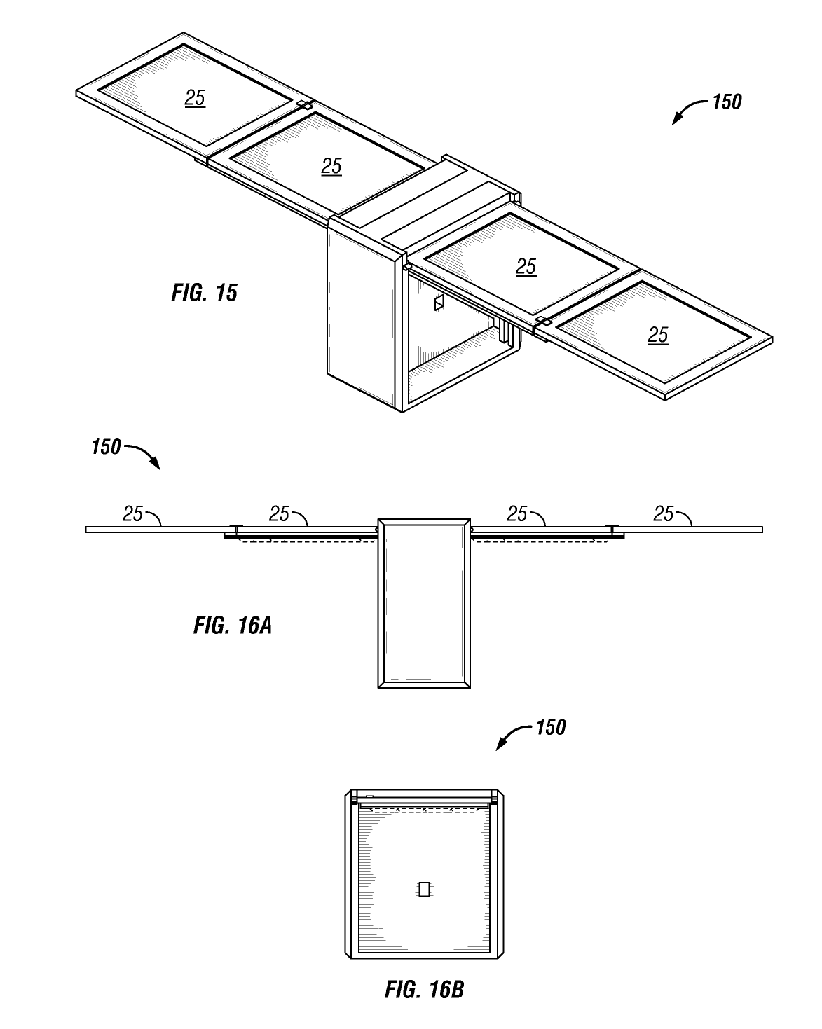

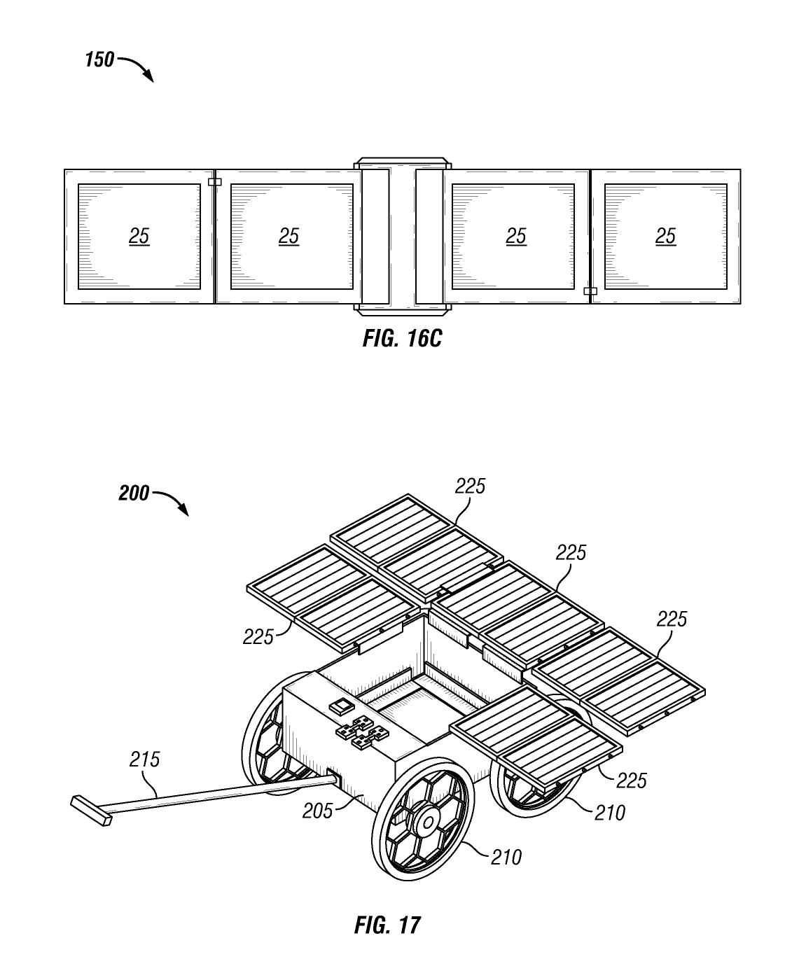

Personal mobile solar deployment systems may encompass a small system weighing less than 60 lbs which has integrated wheels and a handle for ease of transport by a single individual. It may also contain integrated straps so that it can be carried on an individual's back similar to a standard backpack. FIG. 13 is an illustrative implementation of a personal mobile solar deployment unit 150 in an undeployed position. FIGS. 14a-14c are illustrative implementations of front, side, and back views a personal mobile solar deployment unit 150 in an undeployed position. FIG. 15 is an illustrative implementation of a personal mobile solar deployment unit 150 in an deployed position. FIGS. 16a-16c are illustrative implementations of front, side, and top views a personal mobile solar deployment unit 150 in an deployed position. As shown, panels 25 may be hinged to allow them to fold out of personal mobile solar deployment unit 150 into a horizontal position.

FIG. 17 is an illustrative implementation of a trailer solar deployment unit 200 in a deployed position. Trailer 205 provides wheels 210, handle 215, and panels 220, 225. Handle 215 allows a user to move and position trailer solar deployment unit 200 as desired. Panels 220 fold out from trailer 205. For example, the center panel 225 folds out from trailer 205, and the side panels 225 fold out from the center panel. However, in other implementations, any suitable deployment mechanism and/or arrangement may be utilized.

Flexible Solar Panels

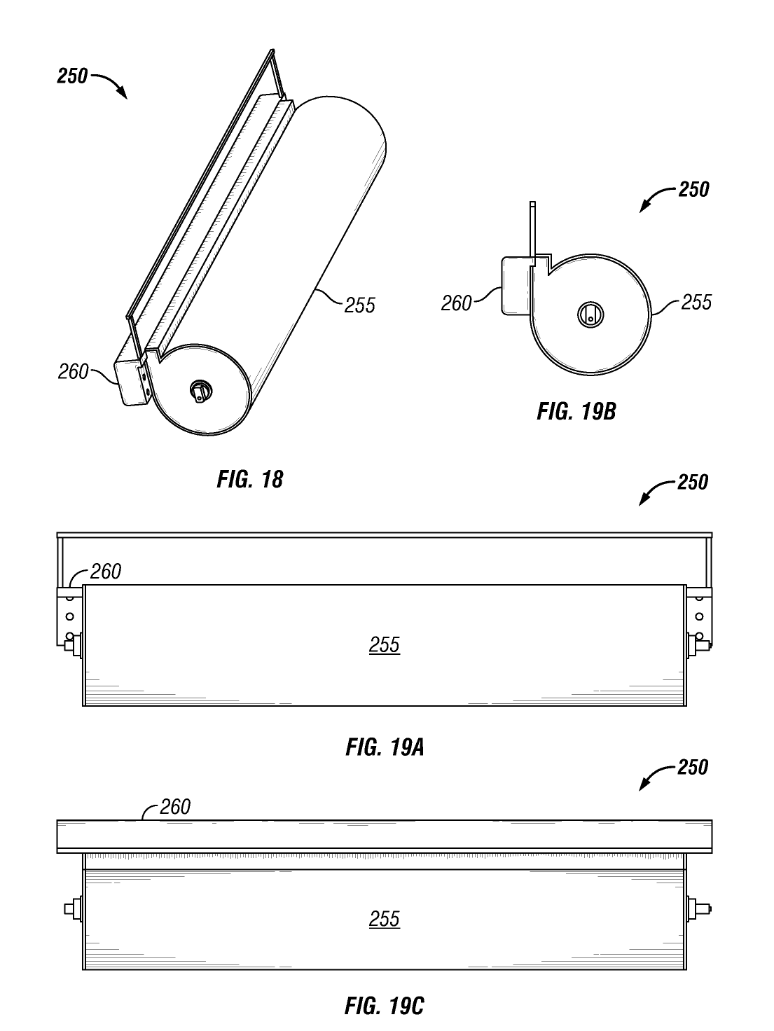

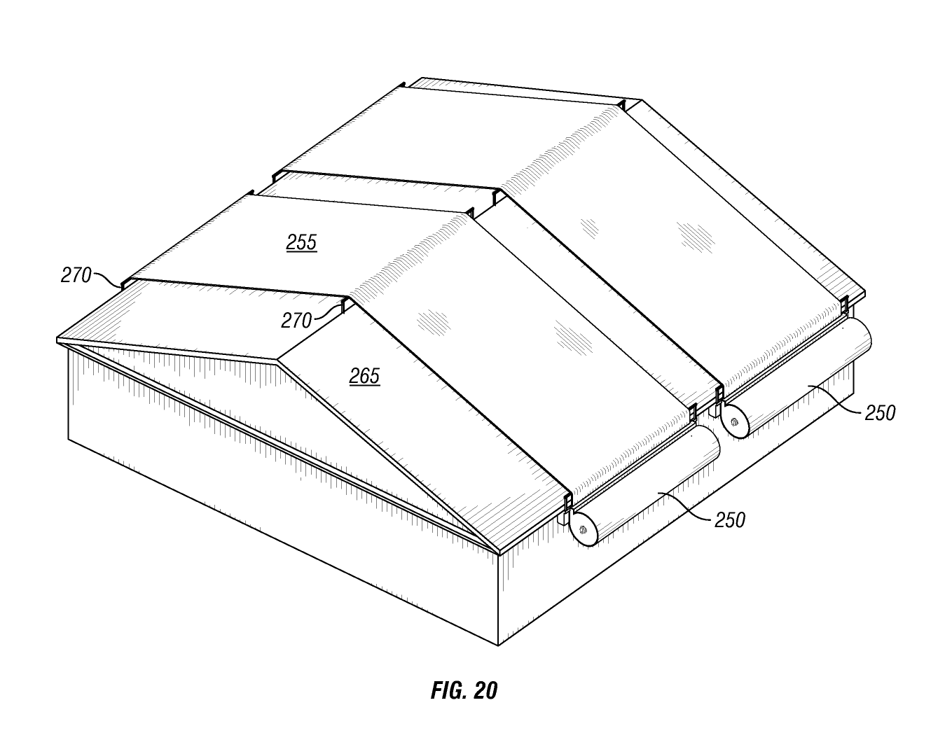

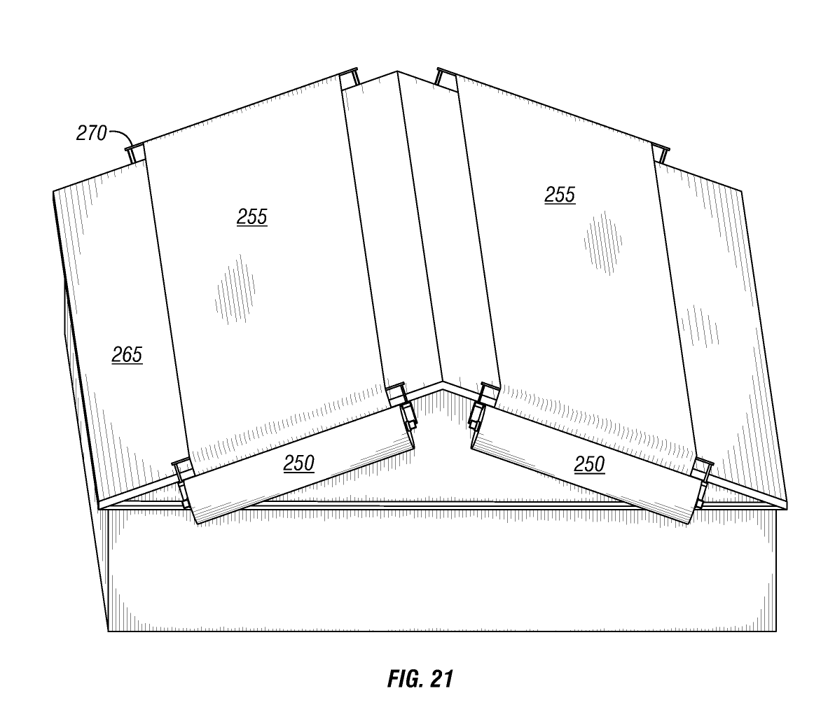

FIG. 18 is an illustrative implementation of a flexible solar panel unit 250. FIGS. 19a-19c are illustrative implementations of plan, elevation, and end view of a flexible solar panel unit 250. FIGS. 20 and 21 are illustrative implementations of a flexible solar panel unit 250 installed on a roof 265. Flexible solar panel unit 250 may utilize flexible solar panels that provide sufficient flex to allow the panels to be rolled up. Rolling mechanism 260 provides a chassis with a rotating shaft around which flexible panel 255 rolls and unrolls about. Additionally, rolling mechanism 260 provides a structure that may be mounted to a desired location, such as a roof or the like. Note that flexible solar panel unit 250 may operate in a similar manner to the various well known window shade designs. For example, in some implementations, rolling mechanism 260 may include a spring (e.g. torsion spring) coupled to the shaft to roll up flexible panel 255 when desired. A locking mechanism may be provide to allow flexible panel 255 to be locked to a desired deployment position. In another implementation, the spring may be substituted with and electric motor to provide motorized unrolling and rolling. In another implementation, flexible panel 255 may be deployed and retracted utilizing a cord or the like coupled to rolling mechanism 260. FIGS. 20-22 are illustrative implementations of a flexible solar panel unit 250 utilizing structural supports 270. Flexible panel 255 unrolls onto structural supports 270 and may be secure the opposite end of the supports. In FIGS. 20-21, structural support 270 is a bar structure that provides support across the width of flexible panel 255 at one or more particular points along the panel. In FIG. 22, structural support 270 supports the full length of the flexible panels 255 along the edges.

The various solar deployment units may be deployed and installed in variety of different manners. For example, FIGS. 20 and 21 illustrate a flexible solar panel unit 250 installed on a roof. FIG. 23 is an illustrative implementation of unfolding solar deployment units 10 installed on a roof 280. Units may be installed on the sides or top of buildings or houses, on the ground, or any suitable location.

Water Purification Systems

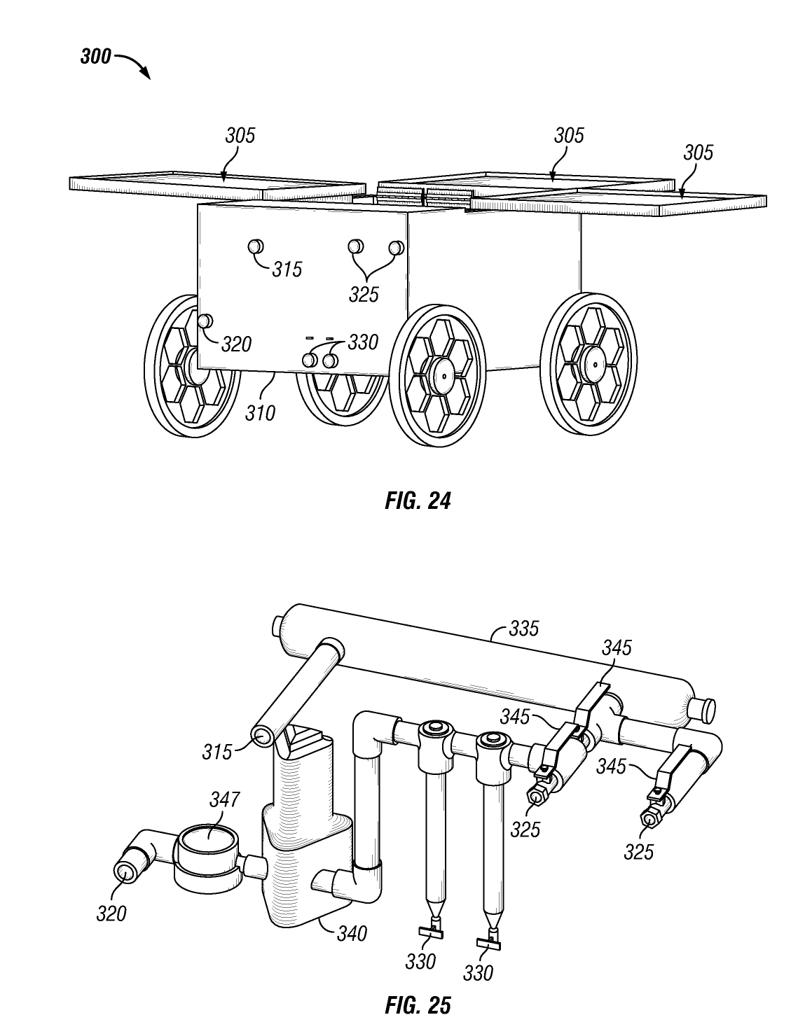

FIG. 24 is an illustrative implementation of a portable water purification system 300. Portable water purification system 300 may utilize any suitable solar deployment unit, such as trailer deployment unit shown in FIG. 17. Portable water purification system 300 may provide panels 305, chassis 310, water out 315, water in 320, module attachment ports 325, and filter flush ports 330. Water in 320 may receive unpurified water that is purified by portable water purification system 300 and outputted to water out 315. Module attachment ports 325 may provide attachment ports for additional modules to be coupled to portable water purification system 300. For example, additional modules may be added to assist pre-chlorination, aeration, coagulation, coagulant aids, sedimentation, filtration, desalination, disinfection, deionization, UV treatment, PH treatment, chemical treatment, or the like during water treatment. Filter flush ports 330 may allow portable water purification system 300 to be flushed and cleaned.

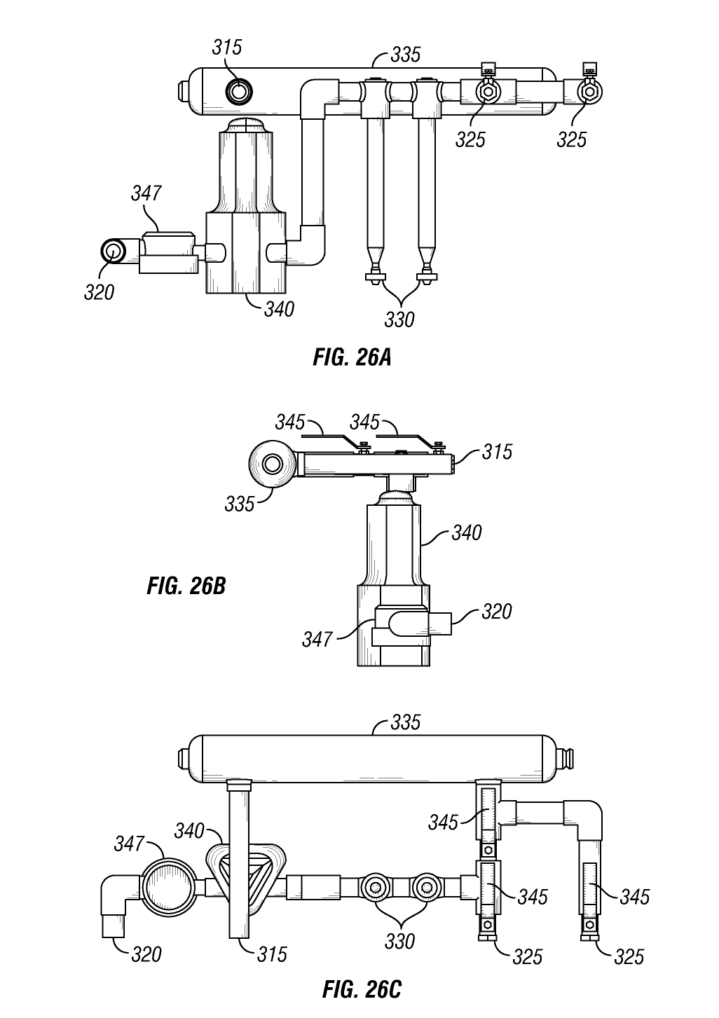

FIG. 25 is an illustrative implementation of the components of a water purification system. FIGS. 26a-26c are illustrative implementations of a plan, elevation, and end view of the components of a water purification system. The water purification system may include water out 315, water in 320, module attachment ports 325, filter flush ports 330, filter 335, pump 340, valves 345, and pre-filter 347. Pre-filter 347 receives water from water in 320 and filters out larger sediment from the water. Pre-filter 347 may provide a easily removable filter that can be taken out and rinsed, flushed, and cleaned out. Water flow through the system is created by pump 340, which causes water to enter through water in 320. The water passes through tubing past filter flush ports 330 and module attachment ports 325.

Valve 345 are utilized to control the flow of water to and from module attachment ports 325. If modules are attached, the valves can be arranged to cause water to flow through module attachment ports 325. Attachment modules may include, but are not limited to, UV treatment, nanofiltration, deionization, disinfection, PH treatment, additive treatment, bio-filtration, and the like. If there are no modules attached, the valves can be arranged to bypass module attachment ports 325.

Water then flows through filter 335 to water out 315. Filter 335 may be any suitable type of filter. For example, filter 335 may provided cone-shaped stainless steel mesh filters. Reversing water flow in the opposite direction allows backwashing and cleaning of filter 335. Further, filter flush ports 330 may be opened to flush biohazardous materials, particulates, debris, bacteria, and the like from the system.

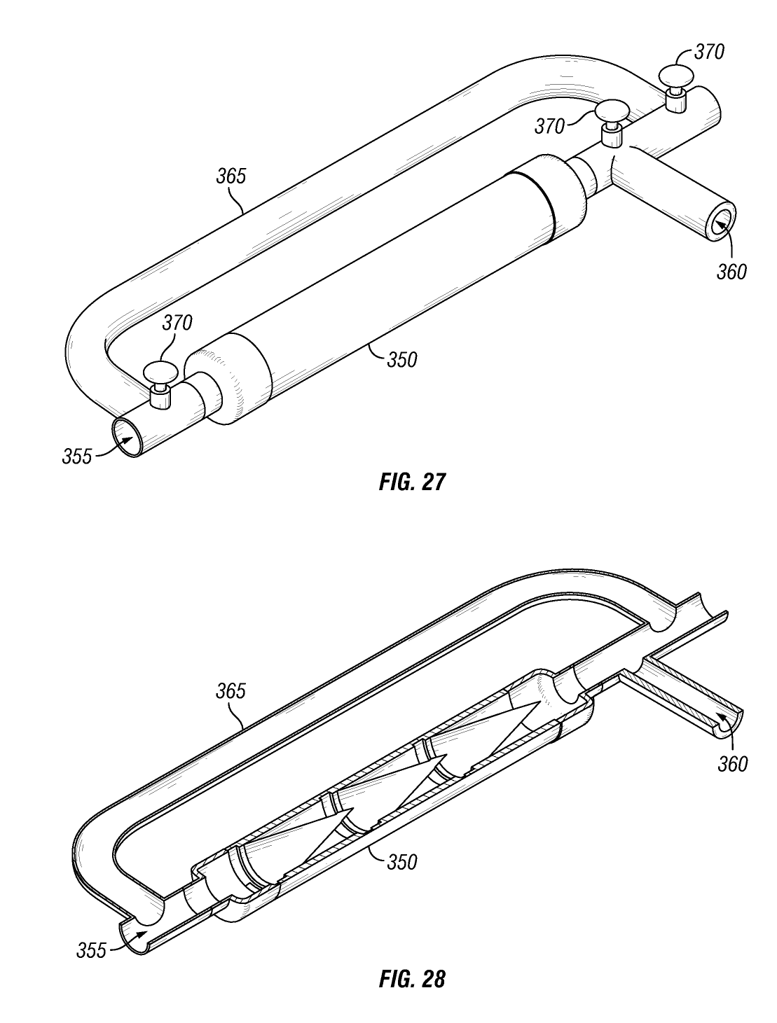

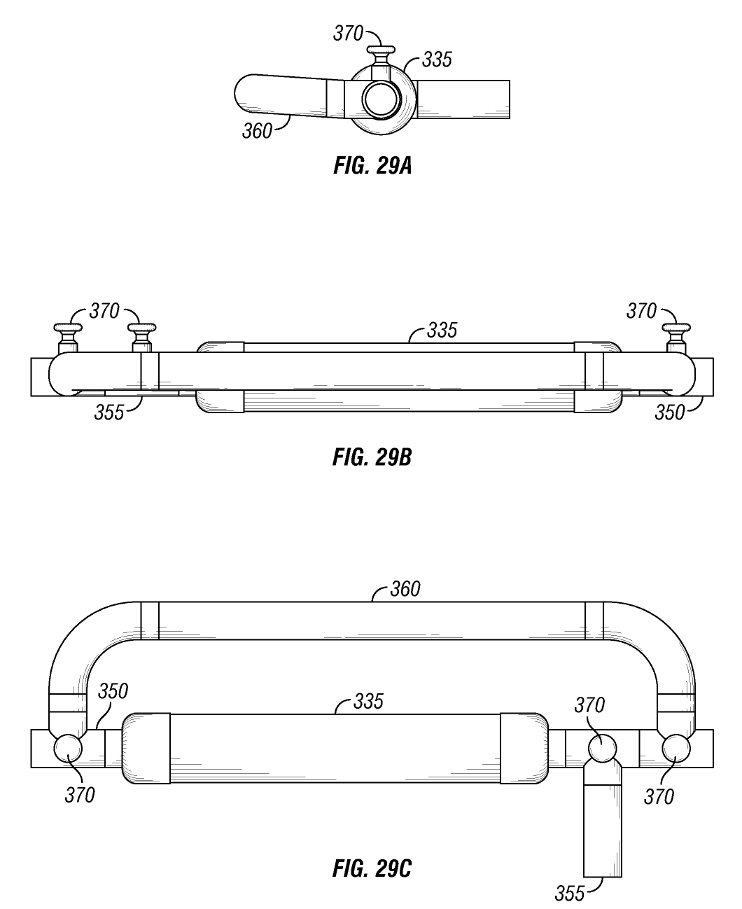

FIG. 27 is an illustrative implementation of a filter 350. FIG. 28 is an illustrative implementation of a cross-section of a filter 350. FIGS. 29a-29c are illustrative implementations of a plan, elevation, and end view of a filter 350. During normal operation, filter 350 receives water through input 355 and the water is filtered as it passes through cone-shaped stainless steel mesh filters in the filter. The filtered water may then be outputted to output 360. Valves 370 are utilized to control flow through filter 350, input 355, output 360, and loop 365. In some situations, it may be desirable to bypass filter 350 when treated water in not necessary, such when watering crops, plants, or the like. Valves 370 may actuated to bypass filter 350, thereby providing pumped water. In some implementations, it may be desirable to incorporate UV treatment, nanofiltration, deionization, disinfection, PH treatment, additive treatment, bio filter and the like to treat biohazardous materials, particulates, debris, bacteria, and the like that may be present in the water. While add-on modules may be connected to the water purification system by module attachment ports 325, the add-on modules may incorporated into the water purification system as well. For example, a bio filter may be incorporated into the system before or after filter 350. In another implementations the bio filter may be provided in loop 365 as an alternative to filter 350.

During a filter cleaning operation, the flow through filter 350 is reversed to flush out particulates, debris, bacteria, and the like. When utilizing a pump that allows the flow to be reversed, the pump may simply be switched to provide reverse flow to clean filter 350. In other implementations, a filter cleaning pump may be attached module attachment port 325 to cause the reverse flow needed to clean filter 350.

Electronic Control System Module Options

Versatile solar deployment system may include a variety of features provided by an electronics control system module. Electronic control system modules may be provided in the electronics housing or chassis of a unit. Electronic control system module may provide solar tracking, electrically powered deployment, plug and play connections to an electrical grid or the like, monitoring, data logging, data communication, remote operation, connection to external power generation, external appliance control, and/or a combination thereof. The system may be GPS controlled and automated to provide solar tracking along a single or multiple axis. In other implementations, the system may utilize sensors (e.g. photo diodes) to provide solar tracking. Solar deployment units may provide DC electrical outputs. The system may provide electrical grid tie module to allow the system to be coupled to an electrical grid that the generated power is to be provided to. The system may also provide power production and monitoring systems with key parameter data logging. The system may include inputs for generators, wind power, hydroelectric power, geothermal, or any other means of AC or DC power production. Further, external power generator controls may be included as well.

When the system provides automatic deployment and retraction, the system will provide controls for deploying and retracting the solar panels. These controls may also control additional modular components installed in system. The system may utilize sensors to detect conditions and control the system in accordance with the detected conditions. Failsafe measures may be incorporated into the system (e.g. fuses, trips, breakers, malfunction alarm, notification by GSM telecommunication, notification by internet, or other forms of communication). The system may wired or wireless connected for network communication. For example, the system may transmit data to a desired location and/or receive control data from a remote location, thereby allowing the system to be operated remotely.

In some implementations, the system provides external connectivity to allow the system to receive software updates, to be serviced, to be programmed, and the like. An internal weather monitoring module may be incorporated to detect weather conditions. The system may include power interfaces that allow the number of units to be scaled to meet desired needs. The number of solar deployment units that may be utilized in a versatile solar deployment system is customizable. A display, such as a LCD, LED, color display, touch screen, or the like, may be utilized as a control module.

The system may also provide automated external appliance control. For example, if excess power is being created by the solar panels without the presence of adequate storage/electrical grid connection, the control module may be capable of adjust an air-conditioning system, hot water boiler, or any suitable appliance to use up the surplus energy.

Electronic System Additional/Optional Components

1. Array expansion module to act as an interconnecting bus for multiple device arrays

2. Cleaning Systems
A. Hydrophobic coating on solar panels
B. Attached to fluid supply that feeds built in sprayers
C. Automatic brushes that can be moved along the system structure
D. Windshield wiper type device
E. Sensors that sense rain and activate C and D systems

3. Battery systems
A. Preassembly battery box that is customizable in size
B. Optional built in charge controllers or transformer
C. Optional built in charge monitor

4. Panel Protection
A. Roll up style plastic or metal cover that can be either manually or automatically deployed
B. Case cover unfolds into protective cover that can be manually or automatically positioned
C. System to automatically retract panels into case
D. Covers are made of transparent plastics that allow the systems to continue to produce power while covered
E. Weather monitor system that can trigger one of the other methods of protection

5. Tandem use portable power generation add-ons
A. Attached generator to supply power on an as needed basis
B. Wind power system built on telescopic tower that can be detached and setup at a distance to prevent shading

6. Water Treatment System
A. Can be designed to purify water to various degrees
B. UV system to kill parasites, bacteria
C. Use of filtration equipment that does not need replacement
D. Cleanable water filter
   Cone shaped stainless steel mesh filters
   Ability to reroute water flow to enable backwashing and cleaning filters
   Attachments for modular add-ons
   Filters water to minimal safe standards
   Modular add-ons designed to treat specific water problems

7. Communications system
A. Built in emergency band radio
B. GPS transponder
C. Satellite uplink

8. Pumping System
Water Pumping system for livestock with appropriate filtration

9. Weather station system
Built in pressure, temperature, wind speed sensors, and the like
Built in wireless communication equipment

Military/Government/NGOs—Charity Specification

For more demanding applications or harsher operating environments, the base system may be modified to have stronger more resistant materials. The system is designed to be operable even after long term storage. Critical components will contain fail-safes and redundancies. The overall operation of these systems is simplified to aid ease of use in inhospitable environments.

Such applications for this system specification include but are not limited to—

1. Emergency/Remote Power Generation

2. Water Treatment.

3. Sanitation

4. Communications/Emergency location transponder

5. Military backup power generation

Solar Farm Specification

Large scale permanent installation may be based upon a trailer mounted with preassembled solar power generation stations utilizing one or more solar deployment units. Each station is designed to deploy its solar panels while anchored from the trailer. The power stations are then connected to a predetermined foundation at the solar farm site. Once the station is locked to the predefined foundations the trailer is detached from the station. This reduces the need for consumable containers, protective packaging, and provides fast installation and ease of panel deployment.

While the invention described herein specifically focuses on the design, construction, and use of a novel versatile unfolding solar deployment system, one of ordinary skills in the art, with the benefit of this disclosure, would recognize the extension of the approach to other systems, solar cells, and material systems. The invention is quite versatile and lends itself to many applications and is readily adapted especially for a solar powered water treatment device as outlined and described in the related figures.

The present invention is well adapted to attain the ends and advantages mentioned as well as those that are inherent therein. The particular embodiments disclosed above are illustrative only, as the present invention may be modified and practiced in different but equivalent manners apparent to those skilled in the art having the benefit of the teachings herein. Furthermore, no limitations are intended to the details of construction, design or use herein shown. It is therefore evident that the particular illustrative embodiments disclosed above may be altered or modified and all such variations are considered within the scope and spirit of the present invention.

What is claimed is the following:

1. A solar deployment unit comprising:
a chassis;
a panel support provided by the chassis; and
one or more solar panels coupled to the panel support, wherein the solar panels are folded together in a undeployed position, and the solar panels are unfolded in a deployed position.

2. The solar deployment unit of claim 1, wherein the solar panels are adjustable to a horizontal position, a vertical position, or an angled position.

3. The solar deployment unit of claim 2, wherein the panel support coupled to a winch, crank, gear, or motor that is utilized to adjust a position of the solar panels.

4. The solar deployment unit of claim 1, further comprising two or more wheels coupled to the chassis.

5. The solar deployment unit of claim 4, further comprising a hitch or handle coupled to the chassis.

6. The solar deployment unit of claim 1, wherein the chassis includes a water purification system.

7. The solar deployment unit of claim 6, wherein the water purification system utilizes a cleanable filter.

8. The solar deployment unit of claim 6, wherein the water purification system provides module attachment ports, and the module attachment ports may be utilized to couple add-ons for the water purification system.

9. The solar deployment unit of claim 1, wherein the add-ons provide UV treatment, nanofiltration, deionization, disinfection, PH treatment, chemical additive treatment, or a combination thereof.

10. The solar deployment unit of claim 1, further comprising a structural support, wherein the structural support provides a panel support receiving the solar panels and one or more struts coupled to the panel support.

11. A solar deployment system comprising:
one or more solar units, each solar unit comprising,
a chassis;
one or more solar panels, wherein the solar panels are retained within the chassis in an undeployed position, and the solar panels extend from the chassis in a deployed position; and
an electronic control unit provided within the chassis, wherein the electronic control unit manages the power generated by the solar panels.

12. The system of claim 11, wherein each solar unit further comprises,
a deployment mechanism coupled to the solar panels, wherein the deployment mechanism is actuated to place the solar panels in the deployed position or to retract the solar panels into the undeployed position; and
an adjustment mechanism coupled to the solar panels, wherein the adjustment mechanism is actuated to adjust the position of the solar panels

13. The system of claim 12, wherein in the deployment mechanism is motorized.

14. The system of claim 12, wherein the adjustment mechanism adjust the solar panels to a horizontal position, a vertical position, or an angled position.

15. The system of claim 14, wherein the adjustment mechanism provides a winch, crank, gear, or motor that is utilized to adjust the solar panels.

16. The system of claim 11, further comprising two or more wheels coupled to the chassis.

17. The system of claim 11, further comprising a hitch or handle coupled to the chassis.

18. The system of claim 11, further comprises a water purification system.

19. The system of claim 18, wherein the water purification system utilizes a cleanable filter.

20. The system of claim 18, wherein the water purification system provides module attachment ports, and the module attachment ports may be utilized to couple add-ons for the water purification system.

21. The system of claim 20, wherein the add-ons provide UV treatment, nanofiltration, deionization, disinfection, PH treatment, chemical additive treatment, or a combination thereof.

22. The system of claim 11, further comprising a structural support, wherein the structural support provides a panel support receiving the solar panels and one or more struts coupled to the panel support.

23. A solar deployment unit comprising:
a rolling mechanism providing a rotating shaft; and
a flexible panel, wherein one end of the flexible panel is secured to the rotating shaft, the flexible panel is rolled around the rotating shaft to retract the flexible panel into an undeployed position, and the flexible panel is unrolled to deploy the flexible panel into a deployed position.

24. The unit of claim 23, further comprising a torsion spring coupled to the rotating shaft.

25. The unit of claim 23, further comprising a cord coupled to the rotating shaft, wherein the cord is pulled in a first direction to deploy the flexible panel and the cord is pulled in a second direction to retract the flexible panel.

26. The unit of claim 23, further comprising a motor coupled to the rotating shaft, wherein the motor rotates in a first direction to deploy the flexible panel and the motor rotates in a second direction to retract the flexible panel.
